(19) United States
(12) Patent Application Publication
(10) Pub. No.: US 2025/0107277 A1
(43) Pub. Date: Mar. 27, 2025

(54) NITRIDE SEMICONDUCTOR LIGHT EMITTING ELEMENT

(71) Applicant: NICHIA CORPORATION, Anan-shi (JP)

(72) Inventors: Shingo KANEHIRA, Anan-shi (JP); Yoshitaka KAWATA, Itano-gun (JP); Hiroki ABE, Komatsushima-shi (JP)

(73) Assignee: NICHIA CORPORATION, Anan-shi (JP)

(21) Appl. No.: 18/897,948

(22) Filed: Sep. 26, 2024

(30) Foreign Application Priority Data
Sep. 27, 2023 (JP) 2023-165225
May 30, 2024 (JP) 2024-087669

(51) Int. Cl. H01L 33/04; H01L 33/02; H01L 33/08; H01L 33/32

(52) U.S. Cl. CPC H10H 20/811; H10H 20/813; H10H 20/8215; H10H 20/825

(57) ABSTRACT

A nitride semiconductor light emitting element includes: a first n-type semiconductor layer, a first p-type semiconductor layer disposed above and in contact with the first n-type semiconductor layer; a first superlattice layer disposed above the first p-type semiconductor layer and containing a p-type impurity; an active layer disposed above the first superlattice layer, a second n-type semiconductor layer disposed above the active layer; a first electrode electrically connected to the first n-type semiconductor layer; and a second electrode electrically connected to the second n-type semiconductor layer.

### CROSS-REFERENCE TO RELATED APPLICATION

This application claims priority to Japanese Patent Application No. 2023-165225 filed on Sep. 27, 2023, and Japanese Patent Application No. 2024-087669 filed on May 30, 2024, the disclosures of which are hereby incorporated by reference in their entireties.

### BACKGROUND

The present disclosure relates to a nitride semiconductor light emitting element.

Nitride semiconductor light emitting elements are required to be improved in luminous efficiency as their use is expanded, and the light emitting element disclosed in Patent Publication No. 2020-501345 is described to be driven with a low current.

### SUMMARY

However, as the application of nitride semiconductor light emitting elements is expanded, it is required to further drive the nitride semiconductor light emitting element with a low current and reduce a forward voltage.

Accordingly, an object of certain embodiments of the present disclosure is to provide a nitride semiconductor light emitting element capable of being driven with a low current and reducing a forward voltage.

According to one embodiment, a nitride semiconductor light emitting element: a first n-type semiconductor layer; a first p-type semiconductor layer disposed above the first n-type semiconductor layer and being in contact with the first n-type semiconductor layer; a first superlattice layer disposed above the first p-type semiconductor layer and containing a p-type impurity; an active layer disposed above the first superlattice layer; a second n-type semiconductor layer disposed above the active layer; a first electrode electrically connected to the first n-type semiconductor layer; and a second electrode electrically connected to the second n-type semiconductor layer.

With the nitride semiconductor light emitting element configured as described above according to the present disclosure, it is possible to provide a nitride semiconductor light emitting element capable of being driven with a low current and reducing a forward voltage.

### BRIEF DESCRIPTION OF DRAWINGS

FIG. 1 is a sectional view of the nitride semiconductor light emitting element according to Embodiment 1;

FIG. 2 is an enlarged sectional view illustrating the first superlattice layer 40 in FIG. 1;

FIG. 3 is a sectional view of the nitride semiconductor light emitting element of Embodiment 2;

FIG. 4 is a sectional view of the nitride semiconductor light emitting element of Embodiment 3;

FIG. 5 is an enlarged sectional view illustrating the second superlattice layer 90 in FIG. 4;

FIG. 6 is a sectional view of the nitride semiconductor light emitting element of Embodiment 4-1; and

FIG. 7 is a sectional view of the nitride semiconductor light emitting element of Embodiment 4-2.

### DETAILED DESCRIPTION

Hereinafter, embodiments and examples for carrying out the present disclosure will be described with reference to the drawings. The nitride semiconductor light emitting elements and the methods for manufacturing nitride semiconductor light emitting elements described below are intended to embody the technical ideas of the present invention, but the present invention is not limited to the described embodiments unless otherwise specified.

In the drawings, members having the same function may be denoted by the same reference numeral. The present invention may be described by being divided into embodiments or examples for convenience in consideration of ease of explanation or understanding of the main points thereof, but partial replacement or combination of the configurations described in different embodiments or examples are possible. In following embodiments and examples, description on matters common to those described in the preceding embodiments or examples will be omitted, and only the differences from the preceding embodiments or examples will be described. In particular, the same operations and effects achieved by the same configuration may not be repeated for every embodiment or example. The sizes, positional relationships, and the like of the members illustrated in the drawings may be exaggerated for clarity of description.

As illustrated in FIG. 1 and the like, the nitride semiconductor light emitting elements of the embodiments according to the present disclosure comprise: a first n-type semiconductor layer 20; a first p-type semiconductor layer 30 disposed above the first n-type semiconductor layer 20 and being in contact with the first n-type semiconductor layer 20; a first superlattice layer 40 disposed above the first p-type semiconductor layer 30 and containing a p-type impurity; a first active layer 50 disposed above the first superlattice layer 40; a second n-type semiconductor layer 60 disposed above the first active layer 50; a first electrode 11 electrically connected to the first n-type semiconductor layer 20; and a second electrode 12 electrically connected to the second n-type semiconductor layer 60.

The nitride semiconductor light emitting elements of the embodiment according to the present disclosure configured as described above includes the first superlattice layer 40, containing the p-type impurity, between the first p-type semiconductor layer 30 and the first active layer 50. With this structure, the forward voltage Vf can be lowered, and the light emission intensity with respect to the voltage applied can be enhanced.

The nitride semiconductor in the present specification refers to any binary to quaternary semiconductor containing nitrogen (N) and at least one of aluminum (Al), gallium (Ga), or indium (In), and can include semiconductors of all compositions in which the composition ratios x and y are varied within the respective ranges in the chemical formula of InₓAl_{y}Ga_{1-x-y}N (0≤x≤1, 0≤y≤1, x+y≤1).

In the following description, nitride semiconductor light emitting elements according to certain embodiments of the present disclosure will be described in detail.

### Embodiment 1

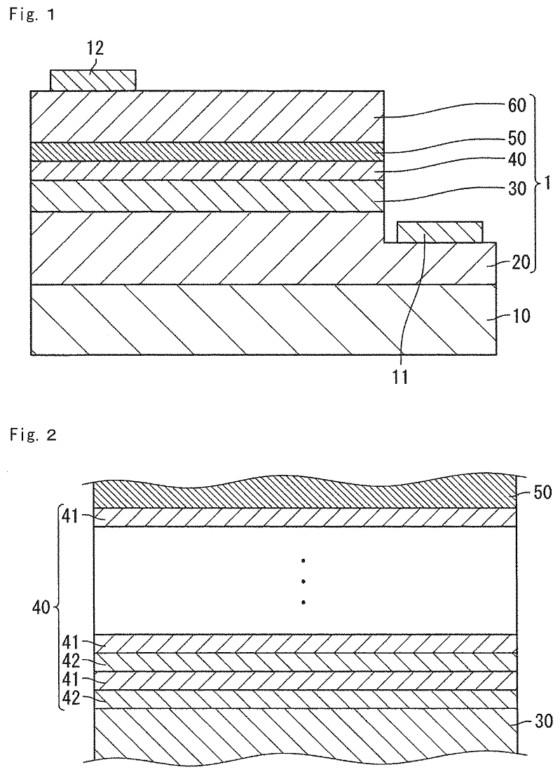

FIG. 1 is a sectional view of the nitride semiconductor light emitting element of Embodiment 1. FIG. 2 is a sectional view of the first superlattice layer 40 in the nitride semiconductor light emitting element of FIG. 1.

As illustrated in FIG. 1, the semiconductor light emitting element of Embodiment 1 includes, for example, a substrate 10 and a first light emitting part 1 disposed above the substrate 10. The first light emitting part 1 includes a first n-type semiconductor layer 20 disposed above the substrate 10, a first p-type semiconductor layer 30 disposed above the first n-type semiconductor layer 20, a first superlattice layer 40 disposed above the first p-type semiconductor layer 30 and containing a p-type impurity, a first active layer 50 disposed above the first superlattice layer 40, and a second n-type semiconductor layer 60 disposed above the first active layer 50. Each of the first n-type semiconductor layer 20, the first p-type semiconductor layer 30, the first superlattice layer 40, the first active layer 50, and the second n-type semiconductor layer is formed of a nitride semiconductor.

Furthermore, the nitride semiconductor light emitting element of Embodiment 1 includes a first electrode 11 electrically connected to the first n-type semiconductor layer 20 by, for example, ohmic contact with the first n-type semiconductor layer 20, and a second electrode 12 electrically connected to the second n-type semiconductor layer 60 by, for example, ohmic contact with the second n-type semiconductor layer 60.

In the nitride semiconductor light emitting element of Embodiment 1 configured as described above, the first n-type semiconductor layer 20 and the first p-type semiconductor layer 30 are in contact with each other, and the current injected from the first electrode 11 is injected into the first active layer 50 via the first n-type semiconductor layer 20 and the first p-type semiconductor layer 30, and the first light emitting part 1 emits light. That is, in the nitride semiconductor light emitting element of Embodiment 1, the first electrode 11 disposed on the first n-type semiconductor layer 20 is a positive electrode, and the second electrode 12 is a negative electrode.

In the nitride semiconductor light emitting element of Embodiment 1 according to the present disclosure, the first superlattice layer 40 containing the p-type impurity is disposed between the first p-type semiconductor layer 30 containing the p-type impurity and the first active layer 50, so that the forward voltage Vf is lowered and the light emission intensity with respect to the voltage applied is enhanced.

That is, the invention of the nitride semiconductor light emitting element according to Embodiment 1 of the present disclosure has been made on the basis of the finding, uniquely obtained by the present inventor, that, in a light emitting element configured such that a current injected from the positive electrode electrically connected to the first n-type semiconductor layer 20 is injected into the first active layer 50 via the first n-type semiconductor layer 20 and the first p-type semiconductor layer 30, disposing the first superlattice layer 40, containing the p-type impurity, between the first p-type semiconductor layer 30, containing the p-type impurity and having p-type conductivity, and the first active layer 50 allows for increasing the efficiency of supplying holes to the first active layer 50, lowering the forward voltage Vf, and increasing the light emission intensity with respect to the applied voltage.

Hereinafter, specific examples and more preferable forms of the first superlattice layer 40 will be described on the basis of the findings obtained by the present inventor.

### <First Superlattice Layer>

FIG. 2 is an enlarged sectional view illustrating the first superlattice layer 40 in the nitride semiconductor light emitting element of Embodiment 1.

As illustrated in FIG. 2, the first superlattice layer 40 includes a first layer 41 and a second layer 42. The first layer 41 and the second layer 42 are alternately stacked. The lattice constant of the second layers 42 is different from the lattice constant of the first layers 41. With the first superlattice layer 40 disposed between the first p-type semiconductor layer 30 and the first active layer 50, it is possible to reduce distortion of crystals of the first active layer 50 due to the difference in lattice constant between the first p-type semiconductor layer 30 and the first active layer 50. Reducing the distortion of the crystals of the first active layer 50 allows for increasing the internal quantum efficiency of the first active layer 50. As a result, luminous efficiency can be improved.

The compositions of the first layer 41 and the second layer 42 are preferably set in consideration of, for example, the composition or band gap of the first active layer 50, and are preferably set in consideration of the composition or band gap of a well layer in a case where the first active layer 50 has a quantum well structure. For example, when the well layer is constituted of an InGaN layer, it is preferable that the first layer 41 and the second layer 42 be layers having a lower composition ratio of In than that of the well layer.

In the first layer 41 and the second layer 42, for example, the lattice constant of the first layer 41 is different from the lattice constant of the second layer 42 due to a difference in In composition ratio. At least one of the first layer 41 or the second layer 42 is a layer doped with a p-type impurity. With at least one of the first layer 41 or the second layer 42 being doped with the p-type impurity, the forward voltage Vf can be lowered as described above. The p-type impurity concentration of at least one of the first layer 41 and the second layer 42 is preferably 1×10¹⁸ cm⁻³ or more and 3×10¹⁹ cm⁻³ or less. In addition, the concentration of the p-type impurity doped in at least one of the first layer 41 or the second layer 42 is preferably lower than the p-type impurity concentration of the first p-type semiconductor layer 30.

For example, the In composition ratio of the first layer 41 can be larger than the In composition ratio of the second layer 42.

In this case, making the p-type impurity concentration of the first layer 41 higher than the p-type impurity concentration of the second layer 42 facilitates reduction in the forward voltage Vf. This is thought to be because allowing In to be distributed densely in the vicinity of the upper surface of the first layer 41 can facilitate reduction in the surface roughness of the upper surface of the first layer 41, and thus the crystallinity of the first superlattice layer 40 is less likely to deteriorate even though the first layer 41 is doped with the p-type impurity.

When the In composition ratio of the first layer 41 is larger than the In composition ratio of the second layer 42 and the p-type impurity concentration of the first layer 41 is larger than the p-type impurity concentration of the second layer 42, the p-type impurity concentration of the first layer 41 is preferably 1×10¹⁸ cm⁻³ or more and 3×10¹⁹ cm⁻³ or less. By setting the p-type impurity concentration of the first layer 41 within such a range, deterioration of the crystallinity of the first superlattice layer 40 can be reduced while increasing the efficiency of supplying holes to the first active layer 50. In this case, the second layer 42 is preferably an undoped layer.

When the In composition ratio of the first layer 41 is larger than the In composition ratio of the second layer 42 and the p-type impurity concentration of the first layer 41 is larger than the p-type impurity concentration of the second layer 42, the thickness of the first layer 41 is preferably less than the thickness of the second layer 42. Reduction in the thickness of the first layer 41 having a relatively large p-type impurity concentration allows for inhibiting deterioration of the crystallinity of the first superlattice layer 40.

In particular, when the first n-type semiconductor layer 20 and the first p-type semiconductor layer 30 are joined by tunnel junction, as will be described later, the impurity concentration in the junction portion between the first n-type semiconductor layer 20 and the first p-type semiconductor layer 30 increases. However, with the first superlattice layer 40, diffusion of impurities into the first active layer 50 can be reduced, so that deterioration of luminous efficiency due to the diffusion of the impurities into the first active layer 50 can be effectively reduced.

In the nitride semiconductor light emitting element of Embodiment 1 including the first superlattice layer 40 configured as described above, disposing the first superlattice layer 40, containing the p-type impurity, between the first p-type semiconductor layer 30, containing the p-type impurity and having p-type conductivity, and the first active layer 50 allows for reducing the forward voltage Vf and increasing the light emission intensity with respect to the applied voltage.

Hereinafter, each constituent of the nitride semiconductor light emitting element of Embodiment 1 will be described in detail.

### Substrate

The material of the substrate 10 is, for example, sapphire, Si, SiC, GaN, or the like. The substrate 10 can be a growth substrate for growing a nitride semiconductor layer. A buffer layer may be disposed between the substrate 10 and the first n-type semiconductor layer 20. The substrate 10 may be removed after a semiconductor layer such as the first n-type semiconductor layer 20 is grown.

First n-Type Semiconductor Layer 20

The first n-type semiconductor layer 20 can be constituted of, for example, a nitride semiconductor layer containing an n-type impurity such as silicon (Si) or germanium (Ge). For example, when the first active layer 50 is constituted of a nitride semiconductor layer containing In, the nitride semiconductor constituting the first n-type semiconductor layer 20 is, for example, an n-type GaN layer, and may contain In, Al, or the like. Further, for example, when the first active layer 50 is constituted of a nitride semiconductor containing Al, the nitride semiconductor constituting the first n-type semiconductor layer 20 is, for example, an n-type AlGaN layer, and may further contain In.

The first n-type semiconductor layer 20 may include one or more n-type nitride semiconductor layers, and for example, the first n-type semiconductor layer 20 preferably includes a nitride semiconductor layer doped with Si as an n-type impurity at a relatively high concentration of 8×10¹⁹ cm⁻³ or more and 8×10²⁰ cm⁻³ or less as a layer that is joined by tunnel junction to the first p-type semiconductor layer 30. The layer that is joined by tunnel junction to the first p-type semiconductor layer 30 is made of n-type GaN doped with Si at a concentration of 8×10¹⁹ cm⁻³ or more and 8×10²⁰ cm⁻³ or less, being a relatively high concentration, and having a thickness of, for example, 1 nm or more and 10 nm or less. The first n-type semiconductor layer 20 preferably includes a nitride semiconductor layer containing an n-type impurity in addition to the layer that is joined by tunnel junction. The n-type impurity concentration of the nitride semiconductor layer containing an n-type impurity other than the layer that is joined by tunnel junction is preferably, for example, 1×10¹⁸ cm⁻³ or more and 1×10¹⁹ cm⁻³ or less, and for example. The first n-type semiconductor layer 20 may be constituted of an n-type GaN layer containing Si as an n-type impurity in an amount of 1×10¹⁸ cm⁻³ or more and 1×10¹⁹ cm⁻³ or less. The first n-type semiconductor layer 20 may partially include an undoped semiconductor layer. As used herein, the undoped semiconductor layer refers to a layer to which no n-type impurity and no p-type impurity are intentionally added. The overall thickness of the first n-type semiconductor layer 20 is, for example, 5 μm or more and 15 μm or less.

<First p-Type Semiconductor Layer 30>

The first p-type semiconductor layer 30 can be constituted of, for example, a nitride semiconductor layer containing a p-type impurity such as magnesium (Mg) or zinc (Zn). For example, when the first active layer 50 is constituted of a nitride semiconductor layer containing In, the nitride semiconductor constituting the first p-type semiconductor layer 30 is, for example, a p-type GaN layer, and may contain In, Al, or the like. Further, for example, when the first active layer 50 is constituted of a nitride semiconductor containing Al, the nitride semiconductor constituting the first p-type semiconductor layer 30 is, for example, a p-type AlGaN layer, and may further contain In.

The first p-type semiconductor layer 30 may include one or more p-type nitride semiconductor layers. For example, the first p-type semiconductor layer 30 preferably includes a nitride semiconductor layer doped with Mg as a p-type impurity at a concentration of 8×10¹⁹ cm⁻³ or more and 8×10²⁰ cm⁻³ or less, being a relatively high concentration, as a layer that is joined by tunnel junction to a layer included as the uppermost layer of the first n-type semiconductor layer 20. The layer that is joined by tunnel junction in the first p-type semiconductor layer is made of p-type GaN doped with Mg at a concentration of 8×10¹⁹ cm-3 or more and 8×10²⁰ cm⁻³ or less, being relatively high concentration, and having a thickness of 1 nm or more and 30 nm or less, for example. The first p-type semiconductor layer 30 preferably includes a nitride semiconductor layer containing a p-type impurity in addition to the layer that is joined by tunnel junction, and the p-type impurity concentration of the nitride semiconductor layer containing a p-type impurity other than the layer that is joined by tunnel junction is preferably, for example, 1×10¹⁸ cm⁻³ or more and 1×10¹⁹ cm⁻³ or less, and for example, the first p-type semiconductor layer 30 may be constituted of a p-type GaN layer containing Mg as a p-type impurity in an amount of 1×10¹⁸ cm⁻³ or more and 1×10¹⁹ cm⁻³ or less. The first p-type semiconductor layer 30 may partially include an undoped semiconductor layer. The overall thickness of the first p-type semiconductor layer 30 may be, for example, 0.04 μm or more and 0.2 μm or less.

### First Active Layer 50

The first active layer 50 is, for example, a nitride semiconductor layer that emits light having a peak emission wavelength of 200 nm or more and 760 nm or less. The first active layer 50 may have, for example, a multiple quantum well structure having a plurality of well layers and a plurality of barrier layers, or a single quantum well structure including one well layer and barrier layers disposed above both sides thereof. When the first active layer 50 has a single or multiple quantum well structure, the well layer is, for example, GaN, InGaN, or AlGaN, and the barrier layer is, for example, AlGaN or GaN.

Second n-Type Semiconductor Layer 60

The second n-type semiconductor layer 60 includes, for example, a nitride semiconductor layer containing an n-type impurity such as silicon (Si). The second n-type semiconductor layer 60 may include one or more n-type nitride semiconductor layers, or may partially include an undoped semiconductor layer. For example, when the first active layer 50 is constituted of a nitride semiconductor layer containing In, the nitride semiconductor constituting the second n-type semiconductor layer 60 is, for example, an n-type GaN layer, and may contain In, Al, or the like. Further, for example, when the first active layer 50 is constituted of a nitride semiconductor containing Al, the nitride semiconductor constituting the second n-type semiconductor layer 60 is, for example, an n-type AlGaN layer, and may further contain In.

The thickness of the second n-type semiconductor layer 60 may be, for example, 0.1 μm or more and 15 μm or less, preferably 0.1 μm or more and 5 μm or less, more preferably 0.1 μm or more and 3 μm or less, and particularly preferably 0.1 μm or more and 1 μm or less. When Si is contained as the n-type impurity, the impurity concentration of the second n-type semiconductor layer 60 may be, for example, 1×10¹⁸ cm⁻³ or more and 1×10¹⁹ cm⁻³ or less.

### <First and Second Electrodes>

The first electrode 11 and the second electrode 12 are electrodes electrically connected to the first n-type semiconductor layer 20 and the second n-type semiconductor layer 60, namely, the n-type semiconductor layers, and can be constituted of, for example, a metal such as Au, Pt, Pd, Rh, Ni, W, Mo, Cr, Ti, Al, or Cu, or an alloy containing these metals. The first electrode 11 and the second electrode 12 may have a single layer structure or a stacked structure in which a plurality of layers are stacked. The first electrode 11 and the second electrode 12 may have, for example, a stacked structure in which a Ti layer, an Al—Si—Cu alloy layer, a Ti layer, a Pt layer, an Au layer, and a Ti layer are stacked in this order.

### Embodiment 2

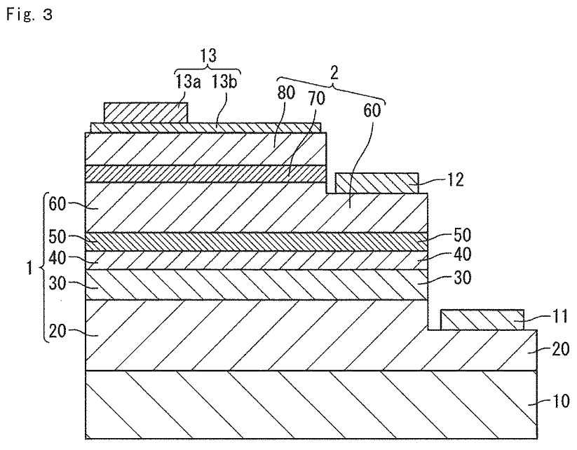

FIG. 3 is a sectional view of the nitride semiconductor light emitting element of Embodiment 2.

As illustrated in FIG. 3, the nitride semiconductor light emitting element of Embodiment 2 includes a second light emitting part 2 on the first light emitting part 1 of the nitride semiconductor light emitting element of Embodiment 1. The second light emitting part 2 includes a second n-type semiconductor layer 60 shared with the first light emitting part, a second active layer 70 disposed above the second n-type semiconductor layer 60, and a second p-type semiconductor layer 80 disposed above the second active layer 70. The nitride semiconductor light emitting element of Embodiment 2 includes a third electrode 13 electrically connected to the second p-type semiconductor layer 80. In the example herein, the third electrode 13 may include a pad electrode 13a and an electrode layer 13b disposed in contact with the second p-type semiconductor layer 80. In the nitride semiconductor light emitting element of Embodiment 2, the second electrode 12 is disposed above a portion of the second n-type semiconductor layer 60 exposed by removing a corresponding portion of the second active layer 70 and a corresponding portion of the second p-type semiconductor layer 80, for example. The first electrode 11 is disposed above the first n-type semiconductor layer 20 in the same manner as in the nitride semiconductor light emitting element of Embodiment 1.

In the nitride semiconductor light emitting element of Embodiment 2 configured as described above, the first electrode 11 functions as a positive electrode of the first light emitting part 1. The third electrode 13 functions as a positive electrode of the second light emitting part 2. The second electrode 12 functions as a negative electrode of the first light emitting part 1 and the second light emitting part 2.

In the nitride semiconductor light emitting element of Embodiment 2, the first light emitting part 1 can be caused to emit light by applying a voltage between the first electrode 11 and the second electrode 12. In addition, the second light emitting part 2 can be caused to emit light by applying a voltage between the third electrode 13 and the second electrode 12. As described above, the first light emitting part 1 and the second light emitting part 2 can be caused to emit light independently from each other.

Even when the first light emitting part 1 and the second light emitting part 2 are simultaneously caused to emit light, the light emission intensities of the first light emitting part 1 and the second light emitting part 2 can be individually controlled by adjusting the voltage applied between the first electrode 11 and the second electrode 12 and the voltage applied between the third electrode 13 and the second electrode 12.

Furthermore, in the nitride semiconductor light emitting element of Embodiment 2, the first light emitting part 1 has the same configuration as that of the nitride semiconductor light emitting element of Embodiment 1, so that the forward voltage Vf can be lowered to increase the light emission intensity with respect to the voltage applied.

In the nitride semiconductor light emitting element of Embodiment 2 configured as described above, the first light emitting part 1 and the second light emitting part 2 may have the same peak emission wavelength or different emission peak wavelengths. In other words, the peak emission wavelength of the first active layer 50 and the peak emission wavelength of the second active layer 70 may be the same or different. In the nitride semiconductor light emitting element of Embodiment 2, the second active layer 70 is located above the first active layer 50. With this structure, when the peak emission wavelength of the first active layer 50 is different from the peak emission wavelength of the second active layer 70, the color mixing performance can be enhanced. When the composition of the first active layer 50 is different from the composition of the second active layer 70, the peak emission wavelength of the first active layer 50 is different from the peak emission wavelength of the second active layer 70. For example, with the In composition ratio of the first active layer 50 different from the In composition ratio of the second active layer 70, the peak emission wavelength of the first active layer 50 is different from the peak emission wavelength of the second active layer 70.

For example, in a nitride semiconductor light emitting element, luminous efficiency varies depending on the peak emission wavelength. In the nitride semiconductor light emitting element of Embodiment 2, as described above, even when the first light emitting part 1 and the second light emitting part 2 are simultaneously caused to emit light, the light emission intensities of the first light emitting part 1 and the second light emitting part 2 can be individually controlled by adjusting the voltage applied between the first electrode 11 and the second electrode 12 and the voltage applied between the third electrode 13 and the second electrode 12. Accordingly, in the nitride semiconductor light emitting element of Embodiment 2, even when the peak emission wavelength of the first active layer 50 is different from the peak emission wavelength of the second active layer 70, appropriate emission color can be easily obtained by adjusting the voltage applied between the first electrode 11 and the second electrode 12 and the voltage applied between the third electrode 13 and the second electrode 12.

Hereinafter, each constituent of the nitride semiconductor light emitting element of Embodiment 2 will be described in detail. Description on the constituent common to Embodiment 1 will be omitted.

### Second Active Layer 70

The second active layer 70 is, for example, a nitride semiconductor layer that emits light having a peak emission wavelength of 200 nm or more and 760 nm or less. The second active layer 70 may have, for example, a multiple quantum well structure having a plurality of well layers and a plurality of barrier layers, or a single quantum well structure including one well layer and barrier layers disposed above both sides thereof. When the second active layer 70 has a single or multiple quantum well structure, the well layer is, for example, GaN, InGaN, or AlGaN, and the barrier layer is, for example, AlGaN or GaN.

Second p-Type Semiconductor Layer 80

The second p-type semiconductor layer 80 can be constituted of, for example, a nitride semiconductor layer containing a p-type impurity such as Mg or Zn. For example, when the second active layer 70 is constituted of a nitride semiconductor layer containing In, the nitride semiconductor constituting the second p-type semiconductor layer 80 is, for example, a p-type GaN layer, and may contain In, Al, or the like. Further, for example, when the second active layer 70 is constituted of a nitride semiconductor containing Al, the nitride semiconductor constituting the second p-type semiconductor layer 80 is, for example, a p-type AlGaN layer, and may further contain In.

The second p-type semiconductor layer 80 may include one or more p-type nitride semiconductor layers. The second p-type semiconductor layer 80 may partially include an undoped semiconductor layer. The overall thickness of the second p-type semiconductor layer 80 may be, for example, 0.04 μm or more and 0.2 μm or less.

### <Third Electrode 13>

The third electrode 13 include, for example, a pad electrode 13a and an electrode layer 13b disposed in contact with the second p-type semiconductor layer 80. For the electrode layer 13b, for example, a light-transmissive metal oxide such as ITO, ZnO, IZO, or In₂O₃, or a light-reflective member such as silver can be used. When using a light-transmissive member as the electrode layer 13b, light can be emitted from the second p-type semiconductor layer 80 side. The pad electrode 13a can be constituted of, for example, a metal such as Au, Pt, Pd, Rh, Ni, W, Mo, Cr, Ti, Al, or Cu, or an alloy containing these metals.

### Embodiment 3

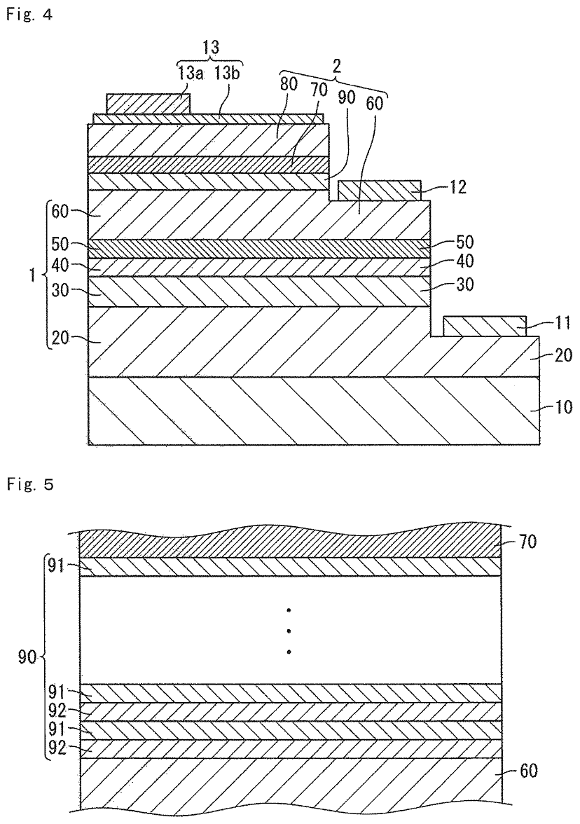

FIG. 4 is a sectional view of the nitride semiconductor light emitting element of Embodiment 3.

As illustrated in FIG. 4, the nitride semiconductor light emitting element of Embodiment 3 is configured similarly to the nitride semiconductor light emitting element of Embodiment 2 except for including the second superlattice layer 90 provided between the second n-type semiconductor layer 60 and the second active layer 70 in the nitride semiconductor light emitting element of Embodiment 2.

That is, in the nitride semiconductor light emitting element of Embodiment 3, the second light emitting part 2 includes the second superlattice layer 90.

FIG. 5 is an enlarged sectional view illustrating the second superlattice layer 90 of FIG. 4.

Hereinafter, the second superlattice layer 90 will be described in detail.

### Second Superlattice Layer 90

In the present embodiment, the second superlattice layer 90 includes a third layer 91 and a fourth layer 92 having a lattice constant different from that of the third layer 91. The second superlattice layer 90 is a layer in which the third layer 91 and the fourth layer 92 are alternately stacked. The third layer 91 and the fourth layer 92 are different, for example, in In composition ratio. With the second superlattice layer 90 disposed between the second n-type semiconductor layer 60 and the second active layer 70, the distortion of crystals of the second active layer 70 due to the difference between the lattice constant of the second n-type semiconductor layer 60 and the lattice constant of the second active layer 70 can be reduced. By reducing the distortion of the crystals of the second active layer 70, the internal quantum efficiency can be increased, and the luminous efficiency can be improved. Furthermore, as described below, various effects can be obtained by appropriately selecting the impurity concentration, composition, thickness, and the like of the third layer 91 and the fourth layer 92.

### Embodiment 3-1

In Embodiment 3-1, the third layer 91 and the fourth layer 92 are both undoped layers. In general, in nitride semiconductors, the crystallinity tends to deteriorate on the upper layer side as the number of layers having different compositions stacked on a growth substrate is increased. Therefore, in the second superlattice layer 90 stacked on the first light emitting part 1, with the third layer 91 and the fourth layer 92 both being undoped layers, deterioration of crystallinity of the second superlattice layer 90 can be reduced.

### Embodiment 3-2

In Embodiment 3-2, at least one of the third layer 91 or the fourth layer 92 is a layer containing an n-type impurity. Examples of the n-type impurity include Si. The n-type impurity concentration of at least one of the third layer 91 or the fourth layer 92 is preferably 1×10¹⁸ cm⁻³ or more and 1×10¹⁹ cm⁻³ or less. With such a concentration, the efficiency of supplying electrons to the second active layer 70 can be improved, and the luminous efficiency can be improved.

In Embodiment 3-2, the third layer 91 is preferably a layer containing an n-type impurity, and the third layer 91 is preferably a layer containing In such as an InGaN layer. With such a structure, the deterioration of the crystallinity of the second superlattice layer 90 caused by the n-type impurity can be reduced while improving the efficiency of supplying electrons to the second active layer 70 by the n-type impurity. It is thought that the deterioration of the crystallinity of the second superlattice layer 90 due to the n-type impurity can be reduced because allowing In to be densely distributed in the vicinity of the upper surface of the third layer 91 allows for reducing the surface roughness of the upper surface of the third layer 91, and thus the crystallinity of the second superlattice layer 90 is less likely to deteriorate even though the n-type impurity is doped in the third layer 91.

In Embodiment 3-2, it is more preferable that the third layer 91 be a layer containing an n-type impurity and containing In, and the fourth layer 92 be a layer having an n-type impurity concentration lower than that of the third layer 91 and an In composition ratio lower than that of the third layer 91. With this structure, the n-type impurity concentration of the second superlattice layer 90 can be increased, and the crystallinity of the second superlattice layer 90 can be made less likely to deteriorate. In this case, the fourth layer 92 may be a layer free of In.

The fourth layer 92 may be an undoped layer.

Furthermore, in Embodiment 3-2, when the third layer 91 is a layer containing an n-type impurity and containing In, and the fourth layer 92 is a layer having an n-type impurity concentration lower than that of the third layer 91 and an In composition ratio lower than that of the third layer 91, the thickness of the third layer 91 is preferably less than the thickness of the fourth layer 92. By reducing the thickness of the third layer 91 having a higher n-type impurity concentration than the fourth layer 92, deterioration of the crystallinity of the second superlattice layer 90 can be reduced.

### Embodiment 4

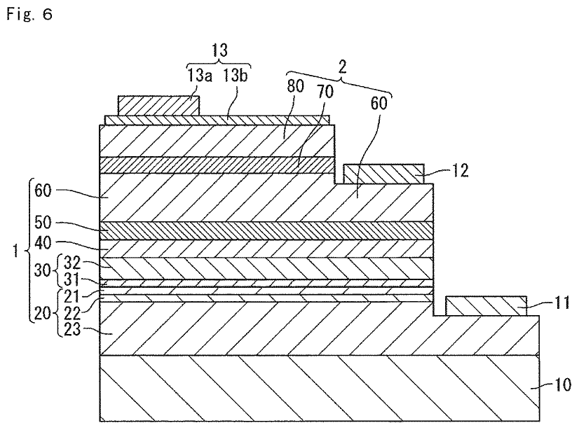

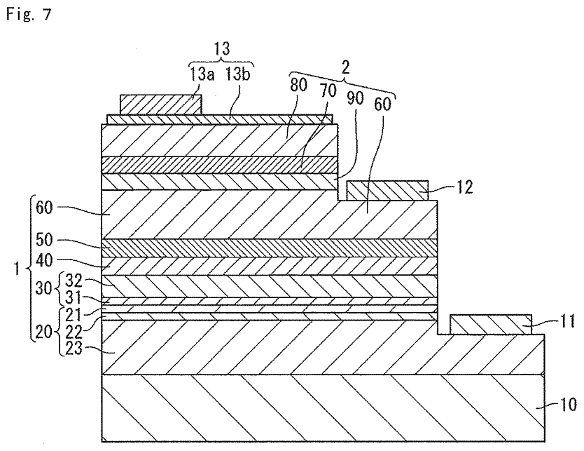

Each of FIGS. 6 and 7 is a sectional view of a nitride semiconductor light emitting element of Embodiment 4.

FIG. 6 is a sectional view of the nitride semiconductor light emitting element of Embodiment 4-1, and FIG. 7 is a sectional view of the nitride semiconductor light emitting element of Embodiment 4-2. As illustrated in FIGS. 6 and 7, in the nitride semiconductor light emitting element of Embodiment 4-1 and the nitride semiconductor light emitting element of Embodiment 4-2, the first n-type semiconductor layer 20 and the first p-type semiconductor layer 30 are similarly configured.

Specifically, in the nitride semiconductor light emitting element of Embodiment 4-1 and the nitride semiconductor light emitting element of Embodiment 4-2,
(a) the first n-type semiconductor layer 20 includes a third superlattice layer 22 and a first junction layer 21 disposed above the third superlattice layer 22 and being in contact with the first p-type semiconductor layer 30, and
(b) the first p-type semiconductor layer 30 includes a second junction layer 31 that is joined by tunnel junction to the first junction layer 21.

In addition, as illustrated in FIG. 6, the nitride semiconductor light emitting element of Embodiment 4-1 is configured similarly to the nitride semiconductor light emitting element of Embodiment 2 except for the first n-type semiconductor layer 20 and the first p-type semiconductor layer 30. As illustrated in FIG. 7, the nitride semiconductor light emitting element of Embodiment 4-2 is configured similarly to the nitride semiconductor light emitting element of Embodiment 3 except for the first n-type semiconductor layer 20 and the first p-type semiconductor layer 30.

Hereinafter, the nitride semiconductor light emitting element of Embodiment 4 will be described in detail.

In the following description, configurations common to the nitride semiconductor light emitting element of Embodiment 4-1 and the nitride semiconductor light emitting element of Embodiment 4-2 will be explained comprehensively with simple reference to “the nitride semiconductor light emitting element of Embodiment 4”.

As described above in Embodiment 1 and the like, it is preferable that the first n-type semiconductor layer 20 include a layer that is joined by tunnel junction to the first p-type semiconductor layer 30, the first p-type semiconductor layer 30 include a layer that is joined by tunnel junction to the first n-type semiconductor layer 20, and that the first n-type semiconductor layer 20 and the first p-type semiconductor layer 30 be joined by tunnel junction. In this configuration, when the first n-type semiconductor layer 20 and the first p-type semiconductor layer 30 are joined by tunnel junction, it is preferable to lower the forward voltage Vf. Accordingly, in the nitride semiconductor light emitting element of Embodiment 4, each of the first n-type semiconductor layer 20 and the first p-type semiconductor layer 30 includes a layer that is joined by tunnel junction, and a superlattice layer is disposed above the substrate 10 side of the layer that is joined by tunnel junction to the second p-type semiconductor layer in the first n-type semiconductor layer 20.

That is, as described above with reference to FIGS. 6 and 7, in the nitride semiconductor light emitting element of Embodiment 4, (a) the first n-type semiconductor layer 20 includes the third superlattice layer 22 and the first junction layer 21, which is disposed above the third superlattice layer 22 and in contact with the first p-type semiconductor layer 30, and (b) the first p-type semiconductor layer 30 includes the second junction layer 31 that is joined to the first junction layer 21 by tunnel junction.

Specifically, as illustrated in FIGS. 6 and 7, in the nitride semiconductor light emitting element of Embodiment 4, the first n-type semiconductor layer 20 includes, in order from the substrate 10 side, an n-type contact layer 23, a third superlattice layer 22, and a first junction layer 21. In the example herein, the first junction layer 21 is located as the uppermost layer on the first p-type semiconductor layer 30 side in the first n-type semiconductor layer 20. In the nitride semiconductor light emitting element of Embodiment 4, the first p-type semiconductor layer 30 includes, in order from the substrate 10 side, a second junction layer 31 and a third p-type semiconductor layer 32. In the example herein, the second junction layer 31 is a layer that is located on the first n-type semiconductor layer 20 side in the first p-type semiconductor layer 30 and is joined by tunnel junction to the first junction layer 21.

In the nitride semiconductor light emitting element of Embodiment 4 configured as described above, the first n-type semiconductor layer 20 and the first p-type semiconductor layer 30 are joined together by tunnel junction, and the first n-type semiconductor layer 20 further includes the third superlattice layer 22. As a result, carriers generated in the layer to be joined by tunnel junction can effectively contribute to light emission, and the forward voltage Vf can thereby be lowered.

Specifically, it is considered that the forward voltage Vf can be lowered for the following reasons.

Preferably, the first junction layer 21 and the second junction layer 31, which are layers to be joined by tunnel junction, are set to have a higher impurity concentration than those of other layers as described later.

Therefore, by using the first junction layer 21 and the second junction layer 31 both having an impurity concentration higher than those of other layers, more carriers are generated than the other layers, and the forward voltage Vf can be lowered.

However, the carriers generated more due to the use of the first junction layer 21 and the second junction layer 31 both having an impurity concentration higher than those of other layers cannot effectively contribute to light emission, and rather, the forward voltage Vf may increase.

The present inventors presumed that defects present in the first junction layer 21 and the second junction layer 31 may inhibit the large number of generated carriers from effectively contributing to light emission.

Specifically, the inventors have thought that the generated carriers are trapped by the defects present in the first junction layer 21 and the second junction layer 31, and thus the carriers cannot be allowed to effectively contribute to light emission.

Accordingly, when the third superlattice layer 22 was disposed in the first n-type semiconductor layer 20 in order to reduce defects generated in the first junction layer 21 and the second junction layer 31, the forward voltage Vf has been able to be lowered, and the invention relating to the nitride semiconductor light emitting element of Embodiment 4 has been made.

Hereinafter, the configurations of the first n-type semiconductor layer 20 and the first p-type semiconductor layer 30 in the nitride semiconductor light emitting element of Embodiment 4 will be described in more detail.

First n-Type Semiconductor Layer 20

In the nitride semiconductor light emitting element of Embodiment 4, the first n-type semiconductor layer 20 includes, in order from the substrate 10 side, the n-type contact layer 23, the third superlattice layer 22, and the first junction layer 21 as described above.

n-Type Contact Layer 23

The n-type contact layer 23 is a layer on which the first electrode 11 is formed, and can be constituted of, for example, a nitride semiconductor layer containing an n-type impurity such as silicon (Si) or germanium (Ge). For example, when the first active layer 50 is constituted of a nitride semiconductor layer containing In, the nitride semiconductor constituting the n-type contact layer 23 is, for example, an n-type GaN layer, and may contain In, Al, or the like. Further, for example, when the first active layer 50 is constituted of a nitride semiconductor containing Al, the nitride semiconductor constituting the n-type contact layer 23 is, for example, an n-type AlGaN layer, and may further contain In.

The n-type impurity concentration of the n-type contact layer 23 is preferably, for example, 1×10¹⁸ cm⁻³ or more and 1×10¹⁹ cm⁻³ or less, and may be formed of, for example, an n-type GaN layer containing Si as an n-type impurity in an amount of 1×10¹⁸ cm⁻³ or more and 1×10¹⁹ cm⁻³ or less.

### Third Superlattice Layer 22

The third superlattice layer 22 is a layer for reducing defects in the first junction layer 21 and the second junction layer 31 joined together by tunnel junction, and is disposed between the n-type contact layer 23 and the first junction layer 21.

The third superlattice layer 22 has a fifth layer and a sixth layer. The fifth layer and the sixth layer are alternately stacked, and the lattice constant of the fifth layer is different from the lattice constant of the sixth layer. By disposing the third superlattice layer 22 between the n-type contact layer 23 and the first junction layer 21, lattice defects in the first junction layer 21 can be reduced as compared with a case where the first junction layer 21 is disposed in contact with the n-type contact layer 23. The compositions of the fifth layer and the sixth layer may be set in consideration of, for example, the compositions or band gaps of the n-type contact layer 23, the first junction layer 21, and the second junction layer 31. For example, when the n-type contact layer 23, the first junction layer 21, and the second junction layer 31 are each constituted of a GaN layer, the fifth layer may be constituted of a GaN layer, and the sixth layer may be constituted of an InGaN layer. When the n-type contact layer 23, the first junction layer 21, and the second junction layer 31 are each constituted of a GaN layer, both the fifth layer and the sixth layer may be constructed with an InGaN layer, and the In composition ratios of the fifth layer and the sixth layer may be different from each other.

The third superlattice layer 22 may contain an n-type impurity, and owing to the fact that the third superlattice layer 22 contains an n-type impurity, it is possible to efficiently supply electrons from the n-type contact layer 23 to the first junction layer 21. When the third superlattice layer 22 contains an n-type impurity, either one or both of the fifth layer and the sixth layer may contain the n-type impurity. When the third superlattice layer 22 contains an n-type impurity, the n-type impurity concentration of the third superlattice layer 22 is preferably 1×10¹⁹ cm⁻³ or less. For example, in the nitride semiconductor element of Embodiment 4-2, the n-type impurity concentration of the third superlattice layer 22 is preferably lower than the n-type impurity concentration of the second superlattice layer. Here, the n-type impurity concentration of the third superlattice layer 22 refers to an average value of the n-type impurity concentration of the entire third superlattice layer 22.

The thickness of the third superlattice layer 22 is preferably thinner as long as a desired effect to reduce defects can be obtained for the first junction layer 21 and the second junction layer 31, and for example, the thickness of the third superlattice layer 22 is preferably thinner than the thickness of the first superlattice layer 40. By reducing the thickness of the third superlattice layer 22, carrier injection into the first p-type semiconductor layer 30 via tunnel junction can be improved without being reduced.

That is, when the third superlattice layer 22 is disposed, there is a possibility that V pits are formed starting from the superlattice layer, and even when V pits are formed, it is possible to inhibit a decrease in carrier injection into the first p-type semiconductor layer 30 due to the formation of the V pits by thinning the third superlattice layer 22.

Specifically, when the third superlattice layer 22 is disposed to be thick and V pits are formed starting from the third superlattice layer 22, the influence of the V pits formed in the third superlattice layer 22 increases, the flatness of the tunnel junction interface decreases, and it is difficult to efficiently obtain a tunnel effect. That is, in order to efficiently obtain the tunnel effect, a certain level or more of flatness is required at the tunnel junction interface, and when the certain level or more of flatness is lost at the tunnel junction interface, the tunnel effect is deteriorated. Therefore, in order to efficiently obtain the tunnel effect, even when V pits are formed starting from the third superlattice layer 22, it is necessary to suppress the influence of the V pits so that a certain level or more of flatness can be secured at the tunnel junction interface, and for this purpose, it is preferable to reduce the thickness of the third superlattice layer 22.

As described above, for example, the thickness of the third superlattice layer 22 is preferably less than the thickness of the first superlattice layer 40. The thickness of the third superlattice layer 22 can be changed, for example, by adjusting the thickness of the fifth layer and the thickness of the sixth layer, respectively, and adjusting the number of pairs including the fifth layer and the sixth layer.

For example, a case where the first superlattice layer 40 includes n pairs each including the first layer 41 and the second layer 42, and the third superlattice layer 22 includes m pairs each including the fifth layer and the sixth layer will be described. Here, n and m are integers of 1 or more. For example, the thickness of the first layer 41 of the first superlattice layer 40 and the thickness of the fifth layer of the third superlattice layer 22 may be 1 nm or more and 3 nm or less. The thickness of the second layer 42 of the first superlattice layer 40 and the thickness of the sixth layer of the third superlattice layer 22 may be 0.5 nm or more and 1.5 nm or less. For example, the number n of the pairs in the first superlattice layer 40 may be set to 16 or more and 60 or less, and the number m of the pairs in the third superlattice layer 22 may be set to 3 or more and 15 or less. The thicknesses of the first superlattice layer 40 and the third superlattice layer 22 may be adjusted within the above-described ranges of the thickness and the number of the pairs, and the thickness of the third superlattice layer 22 may be made less than the thickness of the first superlattice layer 40.

For example, the first layer 41 and the fifth layer are made to have the same thickness, the second layer 42 and the sixth layer are made to have the same thickness, and the number of the pairs m in the third superlattice layer 22 is made less than the number of the pairs n in the first superlattice layer 40. As a result, the thickness of the third superlattice layer 22 can be made less than the thickness of the first superlattice layer 40.

When the first layer 41 of the first superlattice layer 40 and the fifth layer of the third superlattice layer 22 are GaN layers, and the second layer 42 of the first superlattice layer 40 and the sixth layer of the third superlattice layer 22 are InGaN layers, for example, the thicknesses of the first layer 41 and the fifth layer made of GaN layers are made larger than the thicknesses of the second layer 42 and the sixth layer.

### First Junction Layer 21

The first junction layer 21 is, for example, a nitride semiconductor layer doped with an n-type impurity at a relatively high concentration of 8×10¹⁹ cm⁻³ or more and 8×10²⁰ cm⁻³ or less, and is a layer that is joined by tunnel junction to the second junction layer 31. The n-type impurity concentration of the first junction layer 21 is higher than the n-type impurity concentration of the n-type contact layer 23.

The thickness of the first junction layer 21 is, for example, 1 nm or more and 10 nm or less. The first junction layer 21 may contain In. Owing to the fact that the first junction layer 21 contains In, the band gap of the first junction layer 21 can be reduced, and the tunnel effect can be easily obtained.

The first junction layer 21 may include two or more layers, for example, may include a GaN layer and an InGaN layer. For example, a GaN layer disposed above the n-type contact layer 23 side and having a thickness of 1 nm or more and 10 nm or less and an InGaN layer having a thickness of, for example, 0.5 nm or more and 5 nm or less may be included. The In composition ratio of the InGaN layer is, for example, 1% or more and 6% or less.

First p-Type Semiconductor Layer 30

In the nitride semiconductor light emitting element of Embodiment 4, the first p-type semiconductor layer 30 includes, in order from the substrate 10 side, a second junction layer 31 and a third p-type semiconductor layer 32.

### Second Junction Layer 31

The second junction layer 31 is, for example, a nitride semiconductor layer doped with a p-type impurity at a relatively high concentration of 8×10¹⁹ cm⁻³ or more and 8×10²⁰ cm⁻³ or less, and is a layer that is joined by tunnel junction to the first junction layer 21. The p-type impurity concentration of the second junction layer 31 is higher than the p-type impurity concentration of the third p-type semiconductor layer 32 described later.

The thickness of the second junction layer 31 may be, for example, 1 nm or more and 30 nm or less. The second junction layer 31 may include two or more layers each containing a p-type impurity at a concentration higher than that of the third p-type semiconductor layer 32. The second junction layer 31 may include, for example, a p-type GaN layer doped with Mg at a concentration of 8×10¹⁹ cm⁻³ or more and 8×10²⁰ cm⁻³ or less and having a thickness of 1 nm or more and 10 nm or less, and a p-type GaN layer doped with Mg at a concentration lower than that of the p-type GaN layer (however, a concentration is within a concentration range of 8×10¹⁹ cm⁻³ or more and 3×10²⁰ cm⁻³ or less) and having a thickness of 10 nm or more and 20 nm or less.

Third p-Type Semiconductor Layer 32

The third p-type semiconductor layer 32 is a nitride semiconductor layer containing a p-type impurity and disposed above the second junction layer 31. The p-type impurity concentration of the third p-type semiconductor layer 32 is preferably, for example, 1×10¹⁸ cm⁻³ or more and 1×10¹⁹ cm⁻³ or less, and may be formed of, for example, a p-type GaN layer containing Mg as a p-type impurity in an amount of 1×10¹⁸ cm⁻³ or more and 1×10¹⁹ cm⁻³ or less.

The nitride semiconductor light emitting elements according to the embodiments of the present disclosure include, for example, the following aspects.

### [Aspect 1]

A nitride semiconductor light emitting element comprising:
a first n-type semiconductor layer;
a first p-type semiconductor layer disposed above the first n-type semiconductor layer and being in contact with the first n-type semiconductor layer;
a first superlattice layer disposed above the first p-type semiconductor layer and containing a p-type impurity;
an active layer disposed above the first superlattice layer;
a second n-type semiconductor layer disposed above the active layer;
a first electrode electrically connected to the first n-type semiconductor layer; and
a second electrode electrically connected to the second n-type semiconductor layer.

### [Aspect 2]

The nitride semiconductor light emitting element according to aspect 1, wherein the first superlattice layer comprises a first layer and a second layer having a lattice constant different from that of the first layer, the first layer and the second layer being alternately stacked, and
the first layer contains In and a p-type impurity.

### [Aspect 3]

The nitride semiconductor light emitting element according to aspect 2, wherein the second layer contains In and a p-type impurity,
a p-type impurity concentration of the second layer is lower than a p-type impurity concentration of the first layer, and
an In composition ratio of the second layer is lower than an In composition ratio of the first layer.

### [Aspect 4]

The nitride semiconductor light emitting element according to aspect 3, wherein the p-type impurity concentration of the first layer is lower than a p-type impurity concentration of the first p-type semiconductor layer.

### [Aspect 5]

The nitride semiconductor light emitting element according to any one of aspects 2 to 4, wherein the p-type impurity concentration of the first layer is 1×10¹⁸ cm⁻³ or more and 3×10¹⁹ cm⁻³ or less.

### [Aspect 6]

The nitride semiconductor light emitting element according to any one of aspects 2 to 5, wherein a thickness of the first layer is less than a thickness of the second layer.

### [Aspect 7]

The nitride semiconductor light emitting element according to any one of aspects 1 to 6, further comprising:
a second active layer disposed above the second n-type semiconductor layer;
a second p-type semiconductor layer disposed above the second active layer; and
a third electrode electrically connected to the second p-type semiconductor layer.

### [Aspect 8]

The nitride semiconductor light emitting element according to aspect 7, further comprising a second superlattice layer disposed between the second n-type semiconductor layer and the second active layer.

### [Aspect 9]

The nitride semiconductor light emitting element according to aspect 8, wherein s. the second superlattice layer comprises a third layer and a fourth layer having a lattice constant different from that of the third layer, the third layer and the fourth layer being alternately stacked, and
the third layer and the fourth layer are undoped layers.

### [Aspect 10]

The nitride semiconductor light emitting element according to aspect 8 or 9, wherein the second superlattice layer comprises a third layer and a fourth layer having a lattice constant different from that of the third layer, the third layer and the fourth layer being alternately stacked, and
the third layer contains an n-type impurity.

### [Aspect 11]

The nitride semiconductor light emitting element according to any one of aspects 8 to 10, wherein the third layer contains In.

### [Aspect 12]

The nitride semiconductor light emitting element according to aspect 11, wherein an n-type impurity concentration of the fourth layer is lower than an n-type impurity concentration of the third layer, and
an In composition ratio of the fourth layer is lower than an In composition ratio of the third layer.

### [Aspect 13]

The nitride semiconductor light emitting element according to any one of aspects 9 to 12, wherein a thickness of the third layer is less than a thickness of the fourth layer.

### [Aspect 14]

The nitride semiconductor light emitting element according to any one of aspects 1 to 4, wherein the first n-type semiconductor layer comprises a third superlattice layer and a first junction layer disposed above the third superlattice layer and being in contact with the first p-type semiconductor layer, and
the first p-type semiconductor layer comprises a second junction layer that is joined by tunnel junction to the first junction layer.

### [Aspect 15]

The nitride semiconductor light emitting element according to aspect 14, wherein a thickness of the third superlattice layer is less than a thickness of the first superlattice layer.

### [Aspect 16]

The nitride semiconductor light emitting element according to aspect 14 or 15, wherein the third superlattice layer contains an n-type impurity.

### [Aspect 17]

The nitride semiconductor light emitting element according to any one of aspects 14 to 16, further comprising:
a second superlattice layer disposed above the second n-type semiconductor layer and containing an n-type impurity;
a second active layer disposed above the second superlattice layer;
a second p-type semiconductor layer disposed above the second active layer;
a third electrode electrically connected to the second p-type semiconductor layer,
wherein an n-type impurity concentration of the third superlattice layer is lower than an n-type impurity concentration of the second superlattice layer.

What is claimed is:

1. A nitride semiconductor light emitting element comprising:
a first n-type semiconductor layer;
a first p-type semiconductor layer disposed above and in contact with the first n-type semiconductor layer;
a first superlattice layer disposed above the first p-type semiconductor layer and containing a p-type impurity;
an active layer disposed above the first superlattice layer;
a second n-type semiconductor layer disposed above the active layer;
a first electrode electrically connected to the first n-type semiconductor layer; and
a second electrode electrically connected to the second n-type semiconductor layer.

2. The nitride semiconductor light emitting element according to claim 1, wherein the first superlattice layer comprises a first layer that contains In and a p-type impurity, and a second layer having a lattice constant different from that of the first layer, the first layer and the second layer being alternately stacked.

3. The nitride semiconductor light emitting element according to claim 2, wherein:
the second layer contains In and a p-type impurity;
a p-type impurity concentration of the second layer is lower than a p-type impurity concentration of the first layer; and
an In composition ratio of the second layer is lower than an In composition ratio of the first layer.

4. The nitride semiconductor light emitting element according to claim 3, wherein the p-type impurity concentration of the first layer is lower than a p-type impurity concentration of the first p-type semiconductor layer.

5. The nitride semiconductor light emitting element according to claim 2, wherein the p-type impurity concentration of the first layer is 1×10¹⁸ cm⁻³ or more and 3×10¹⁹ cm⁻³ or less.

6. The nitride semiconductor light emitting element according to claim 2, wherein a thickness of the first layer is less than a thickness of the second layer.

7. The nitride semiconductor light emitting element according to claim 1, further comprising:
a second active layer disposed above the second n-type semiconductor layer;
a second p-type semiconductor layer disposed above the second active layer; and
a third electrode electrically connected to the second p-type semiconductor layer.

8. The nitride semiconductor light emitting element according to claim 7, further comprising a second superlattice layer disposed between the second n-type semiconductor layer and the second active layer.

9. The nitride semiconductor light emitting element according to claim 8, wherein:
the second superlattice layer comprises a third layer, and a fourth layer having a lattice constant different from that of the third layer, the third layer and the fourth layer being alternately stacked; and
the third layer and the fourth layer are undoped layers.

10. The nitride semiconductor light emitting element according to claim 8, wherein:
the second superlattice layer comprises a third layer, and a fourth layer having a lattice constant different from that of the third layer, the third layer and the fourth layer being alternately stacked; and
the third layer contains an n-type impurity.

11. The nitride semiconductor light emitting element according to claim 10, wherein the third layer contains In.

12. The nitride semiconductor light emitting element according to claim 11, wherein:
an n-type impurity concentration of the fourth layer is lower than an n-type impurity concentration of the third layer; and
an In composition ratio of the fourth layer is lower than an In composition ratio of the third layer.

13. The nitride semiconductor light emitting element according to claim 10, wherein a thickness of the third layer is less than a thickness of the fourth layer.

14. The nitride semiconductor light emitting element according to claim 1, wherein:
the first n-type semiconductor layer comprises a third superlattice layer, and a first junction layer disposed above the third superlattice layer and being in contact with the first p-type semiconductor layer; and
the first p-type semiconductor layer comprises a second junction layer that is joined by tunnel junction to the first junction layer.

15. The nitride semiconductor light emitting element according to claim 14, wherein a thickness of the third superlattice layer is less than a thickness of the first superlattice layer.

16. The nitride semiconductor light emitting element according to claim 14, wherein the third superlattice layer contains an n-type impurity.

17. The nitride semiconductor light emitting element according to claim 16, further comprising:
a second superlattice layer disposed above the second n-type semiconductor layer and containing an n-type impurity;
a second active layer disposed above the second superlattice layer;
a second p-type semiconductor layer disposed above the second active layer; and
a third electrode electrically connected to the second p-type semiconductor layer,
wherein an n-type impurity concentration of the third superlattice layer is lower than an n-type impurity concentration of the second superlattice layer.
